(19) United States
(12) Patent Application Publication
(10) Pub. No.: US 2011/0192820 A1
(43) Pub. Date: Aug. 11, 2011

(54) ATOMIC LAYER ETCHING APPARATUS AND ETCHING METHOD USING THE SAME

(75) Inventors: Geun-Young Yeom, Seoul (KR); Woong-Sun Lim, Seoul (KR); Sang-Duk Park, Austin, TX (US); Yi-Yeon Kim, Chungcheongnam-do (KR); Byoung-Jae Park, Gyeonggi-do (KR); Je-Kwan Yeon, Gyeonggi-do (KR)

(73) Assignee: SUNGKYUNKWAN UNIVERSITY Foundation for Corporate Collaboration, Suwon-Si (KR)

(21) Appl. No.: 12/712,944

(22) Filed: Feb. 25, 2010

(30) Foreign Application Priority Data
Feb. 9, 2010 (KR) 10 2010 0011929

(51) Int. Cl. B44C 1/22; H01L 21/3065

(52) U.S. Cl. 216/67; 156/345.26

(57) ABSTRACT

An atomic layer etching apparatus using reactive radicals and neutral beams and an etching method using the same are provided. The atomic layer etching apparatus includes a reaction chamber including a stage on which a substrate to be etched is seated, a plasma generator including a plasma chamber configured to supply reactive radicals and neutral beams into the reaction chamber and receive a source gas to generate plasma, an inductive coil configured to surround the exterior of the plasma chamber to generate an electric field, a grid assembly disposed at a lower part of the plasma chamber and including first, second and third grids for extracting ion beams, and a reflective body disposed under the grid assembly and configured to supply electrons to the ion beams to convert the ion beams into neutral beams, a shutter installed between the plasma generator and the reactive chamber and configured to adjust supply of the neutral beams into the reaction chamber, a purge gas supply part configured to supply a purge gas into the reaction chamber, and a controller configured to control supply of the source gas, an etching gas and the purge gas, and opening/closing of the shutter.

### CLAIM FOR PRIORITY

This application claims priority to Korean Patent Application No. 2010-11929 filed on Feb. 9, 2010 in the Korean Intellectual Property Office (KIPO), the entire contents of which are hereby incorporated by reference.

### BACKGROUND

1. Technical Field

Example embodiments of the present invention relate in general to the field of an atomic layer etching apparatus and an etching method using the same, and more specifically, to an atomic layer etching apparatus using reactive radicals and neutral beams, and an etching method using the same.

2. Related Art

As high integration of semiconductor devices has been continuously needed, in recent times, design rules for semiconductor integration circuits have been further reduced so that critical dimensions of 0.25 μm or less are required. Now, as etching equipment for implementing a nanometer-sized semiconductor device, ion-enhanced etching equipment such as a high density plasma etcher, a reactive ion etcher, etc., are mainly used. However, since a large amount of ions for performing an etching process exist in such etching equipment and the ions collide with a semiconductor substrate or a specific material layer on the semiconductor substrate with hundreds eV of energy, physical and electrical damage to the semiconductor substrate or the specific material layer may occur.

Therefore, since the physical and electrical damage to the nanometer-sized semiconductor device caused by the ions decrease reliability of the device and further lower productivity, developments of new concepts of semiconductor etching equipment and etching methods adaptable to higher integration of semiconductor devices and further reduction in design rules are still needed.

Meanwhile, in the case of an atomic layer etching process using atomic beams or neutral beams, which has recently been developed, since progression directions of the neutral radicals and neutral beams, which are diffused and emitted from plasma, coincide with each other, an effect on the radicals caused by the etching process must be substantially considered, and a pattern line of an etched part may be substantially undercut due to the radicals.

### SUMMARY

Accordingly, example embodiments of the present invention provide an atomic layer etching apparatus capable of adsorbing reactive radicals to a layer to be etched, simultaneously removing a surface material of the layer and the reactive radicals, and performing an atomic layer etching process.

Example embodiments of the present invention also provide an etching method using the atomic layer etching apparatus.

Example embodiments of the present invention provide an atomic layer etching apparatus including: a reaction chamber including a stage on which a substrate to be etched is seated; a plasma generator including a plasma chamber configured to supply reactive radicals and neutral beams into the reaction chamber and receive a source gas to generate plasma, an inductive coil configured to surround the exterior of the plasma chamber to generate an electric field, a grid assembly disposed at a lower part of the plasma chamber and including first, second and third grids for extracting ion beams, and a reflective body disposed under the grid assembly and configured to supply electrons to the ion beams to convert the ion beams into neutral beams; a shutter installed between the plasma generator and the reactive chamber and configured to adjust supply of the neutral beams into the reaction chamber; a purge gas supply part configured to supply a purge gas into the reaction chamber; and a controller configured to control supply of the source gas, an etching gas and the purge gas, and opening/closing of the shutter.

In some example embodiments, the first, second and third grids of the grid assembly may be spaced apart a predetermined distance from each other, and the first grid may receive a positive voltage, the second grid may receive a negative voltage, and the third grid may receive a positive voltage to extract and accelerate ion beams.

Example embodiments of the present invention also provide an etching method using an atomic layer etching apparatus, including: loading a substrate, in which a layer to be etched is exposed, on a stage in a reaction chamber; reactively supplying radicals generated from a plasma generator disposed at an upper part of the reaction chamber into the reaction chamber to adsorb the radicals to a surface of the exposed layer; supplying a purge gas through a purge gas supply part installed at one side of the reaction chamber, and removing excessive radicals remaining after the adsorption; irradiating neutral beams generated from the plasma generator to the layer to which the radicals are adsorbed, and removing a surface material of the layer with the radicals; and supplying a purge gas and removing etching byproducts generated by irradiation of the neutral beams.

In some example embodiments, the plasma generator may include a plasma chamber configured to receive a source gas to generate plasma, an inductive coil configured to surround the exterior of the plasma chamber to generate an electric field, a grid assembly disposed at a lower part of the plasma chamber and including first, second and third grids for extracting ion beams, and a reflective body disposed under the grid assembly and configured to supply electrons to the ion beams to convert the ion beams into neutral beams.

In other example embodiments, in supplying the reactive radicals, electric power may not be supplied to the grid assembly.

In still other example embodiments, in irradiating the neutral beams and removing the surface material of the layer to be etched and the radicals, the first grid of the grid assembly may receive a positive voltage, the second grid may receive a negative voltage, and the third grid may receive a positive voltage.

In yet other example embodiments, in irradiating the neutral beams and removing the surface material of the layer to be etched and the radicals, the voltages applied to the second and third grids may be adjusted to control acceleration energy of the neutral beams such that sputtering is not generated from the surface of the layer to be etched.

In yet other example embodiments, in irradiating the neutral beams and removing the surface material of the layer to be etched and the radicals, ion beams may be extracted from an ionic material in plasma through the grid assembly, and converted into neutral beams by the reflective body disposed on a progression path of the extracted ion beams and then irradiated.

In yet other example embodiments, the purge gas may be nitrogen gas.

### BRIEF DESCRIPTION OF DRAWINGS

Example embodiments of the present invention will become more apparent by describing in detail example embodiments of the present invention with reference to the accompanying drawings, in which:

FIG. 1 is a conceptual view of an atomic layer etching apparatus in accordance with an example embodiment of the present invention;

FIG. 2 is a conceptual view of an ion source of the atomic layer etching apparatus in accordance with an example embodiment of the present invention; and

FIGS. 3 to 7 are views illustrating an etching method using an atomic layer etching apparatus in accordance with an example embodiment of the present invention.

### DESCRIPTION OF EXAMPLE EMBODIMENTS

Example embodiments of the present invention are disclosed herein. However, specific structural and functional details disclosed herein are merely representative for purposes of describing example embodiments of the present invention, however, example embodiments of the present invention may be embodied in many alternate forms and should not be construed as limited to example embodiments of the present invention set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “″including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present invention will be described in detail with reference to the accompanying drawings. For the purpose of the entire understanding in description of the present invention, like numbers refer to like elements throughout the description of the figures, and detailed description thereof will not be repeated.

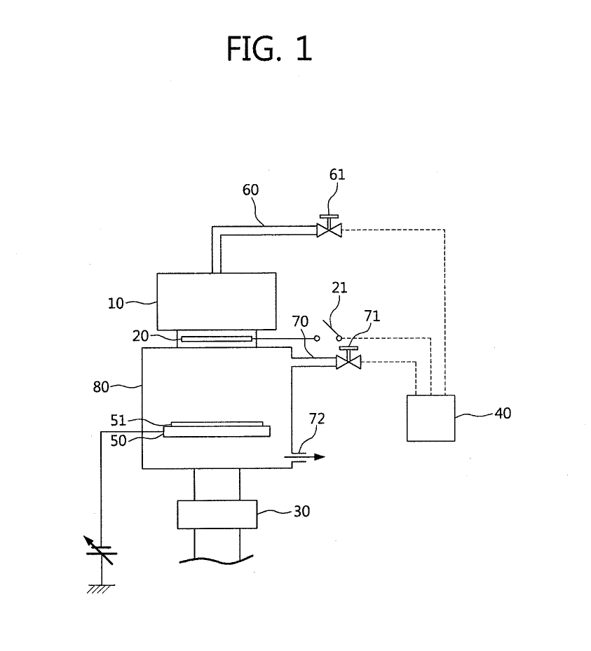

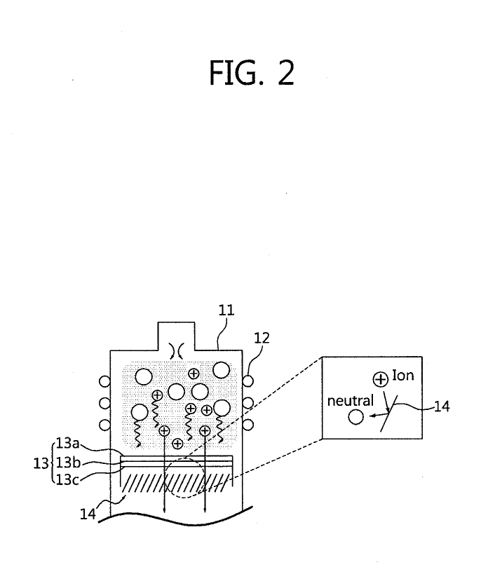

FIG. 1 is a conceptual view of an atomic layer etching apparatus in accordance with an example embodiment of the present invention, and FIG. 2 is a conceptual view of an ion source of the atomic layer etching apparatus in accordance with an example embodiment of the present invention.

Referring to FIGS. 1 and 2, an atomic layer etching apparatus in accordance with an example embodiment of the present invention includes a reaction chamber 80 including a stage 50 on which a substrate 51 is seated to be etched, a plasma generator 10 for generating neutral beams and reactive radicals, a shutter 20 for adjusting supply of the neutral beams and radicals into the reaction chamber 80, and a controller 40 for controlling supply of a source gas and a purge gas and controlling opening/closing of the shutter 20.

A purge gas supply pipe 70 is connected to one side of an upper part of a sidewall of the reaction chamber 80 to supply a purge gas thereinto, and supply of the purge gas is controlled by a purge gas supply valve 71 installed at the purge gas supply pipe 70. In addition, a process gas discharge port 72 is installed at one side of a lower part of the sidewall of the reaction chamber 80 to discharge the purge gas, excessive radicals, or etching byproducts. Further, a discharge pump 30, for example, a turbo molecular pump, is installed at a lower end of the reaction chamber 80 to maintain a high vacuum pressure in the reaction chamber 80.

A source gas supply pipe 60 is connected to an upper part of the plasma generator 10 to supply a source gas, and supply of the source gas is controlled by a source gas supply valve 61 installed at the source gas supply pipe 60. In addition, the shutter 20 is installed at the lowermost end of the plasma generator 10, and connected to a shutter switch 21 to control opening/closing of the shutter 20.

Further, the plasma generator 10 includes a plasma chamber 11 for receiving a source gas through the source gas supply pipe 60 and generating plasma, an inductive coil 12 surrounding the exterior of the plasma chamber 11 to generate an electric field, a grid assembly 13 disposed at a lower part of the plasma chamber 11 and constituted by first, second and third grids 13a, 13b and 13c to extract ion beams, and a reflective body 14 disposed under the grid assembly 13 to supply electrons to the ion beams and convert the ion beams into neutral beams.

A high positive (+) voltage of tens to hundreds of volts (V) is applied to the uppermost first grid 13a of the grid assembly 13, a relatively lower positive (+) voltage than that of the first grid 13a is applied to the lowermost third grid 13c so that high ion energy cannot be acquired during a neutralization process, and a voltage of 0 V is applied to the second grid 13b by ground.

The first, second and third grids 13a, 13b and 13c of the grid assembly 13 act as electrically insulated ion extraction electrodes and are spaced apart a predetermined distance from each other. The reason for constituting the grid assembly 13 by the plurality of grids as described above is to adjust characteristics such as energy of extracted ion beams, etc. For example, the first grid 13a receives a positive (+) voltage to extract and accelerate ions in plasma to extract ion beams, the second grid 13b receives a negative (−) voltage to decelerate the extracted ion beams, and the third grid 13c receives a positive (+) voltage to concentrate and accelerate the ion beams.

In addition, while the first, second and third grids 13a, 13b and 13c are not shown in the figures, each grid has a porous disc shape in which a plurality of through-holes are vertically formed.

Further, the reflective body 14 is disposed on a progression path of the ion beams. Therefore, the ion beams collide with the reflective body 14 and are reflected therefrom, and electrons are provided to the ion beams while colliding with the reflective body 14 to convert the ion beams into neutral beams.

Meanwhile, a supply amount, a supply time, an opening/closing time, etc., of the source gas supply valve 61, the purge gas supply valve 71 and the shutter switch 21 are generally controlled by the controller 40.

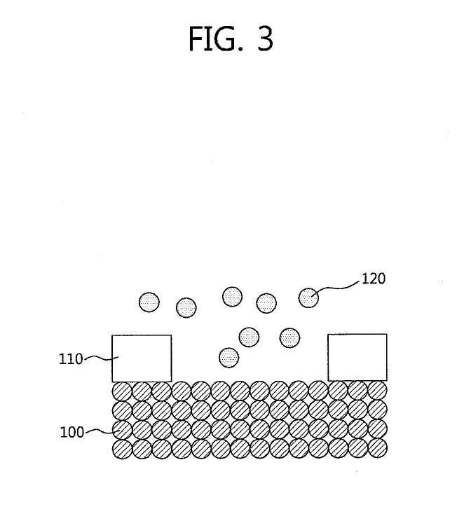

FIGS. 3 to 7 are views illustrating an etching method using an atomic layer etching apparatus in accordance with an example embodiment of the present invention, which will be described with operation of the atomic layer etching apparatus in accordance with an exemplary embodiment of the present invention shown in FIGS. 1 and 2.

Referring to FIG. 3, first, a substrate 51, in which a layer 100 to be etched is exposed, is seated on a stage 50 of an atomic layer etching apparatus in accordance with an exemplary embodiment of the present invention.

Here, an etching mask 110 is formed on the substrate 51 to be etched to expose a portion of the substrate 51.

The layer 100 may be formed of single crystal silicon or polysilicon, or may be a semiconductor substrate including at least silicon. The layer 100 may be formed on the semiconductor substrate to a predetermined thickness.

The etching mask 110 may be formed of photoresist, but the present invention is not limited thereto. That is, the etching mask 110 may be formed of a material that does not react with or adsorb the reactive radicals, unlike the layer 100. In addition, the etching mask 110 may be formed by typical photolithography and etching processes.

After seating the substrate 51 on the stage 50, a controller 40 controls a source gas supply valve 61 to open so that a source gas is supplied into a plasma generator 10 through a source gas supply pipe 40.

When the source gas is supplied into the plasma generator 10, electric power is applied to an inductive coil surrounding the exterior of the plasma chamber 11 to generate plasma in the plasma chamber 11. Here, a plurality of ions and electrons and reactive radicals exist in the plasma.

When plasma is generated, a shutter 20 is opened so that the reactive radicals are injected into a reaction chamber 80. Here, an ionic material is also injected into the reaction chamber 80 together with the reactive radicals.

Meanwhile, since the radical has a relatively larger weight than the ionic material, the radical can be more rapidly lowered than the ionic material. In addition, the ionic material receives electrons from a reflective body 14 to be converted to a neutral material.

Further, electric power is not applied to a grid assembly 13 of the plasma generator 10 to prevent acceleration of the ion. This serves to prevent acceleration of the ionic material having a positive (+) polarity during injection into the reaction chamber 80.

This is because the layer 100 may be etched when the ionic material is accelerated and neutralized by the reflective body 14.

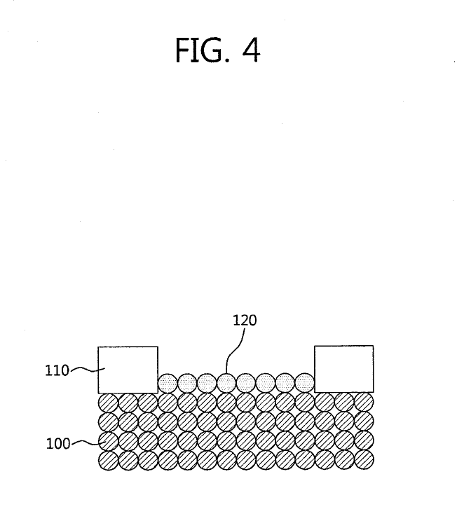

Referring to FIG. 4, reactive radicals 120 injected into the reaction chamber 80 are adsorbed onto the layer 100 of the substrate 51. Here, the reactive radicals 120 react with a material of the layer 100 to cover the uppermost part of the layer 100 in a form similar to atomic layer deposition.

When the reactive radicals 120 are adsorbed onto an upper part of the layer 100, the shutter 20 is closed to block supply of the reactive radicals into the reaction chamber 80 from the plasma generator 10.

Next, a purge gas is supplied into the reaction chamber 80 through a purge gas supply pipe 70 to discharge a purge gas through a process gas discharge port 72 under control of the controller 40. Here, the purge gas may use an inert gas, for example, nitrogen (N₂) gas. In addition, the purge gas is discharged through the process gas discharge port 72 together with excessive reactive radicals remaining after adsorption onto the layer 100.

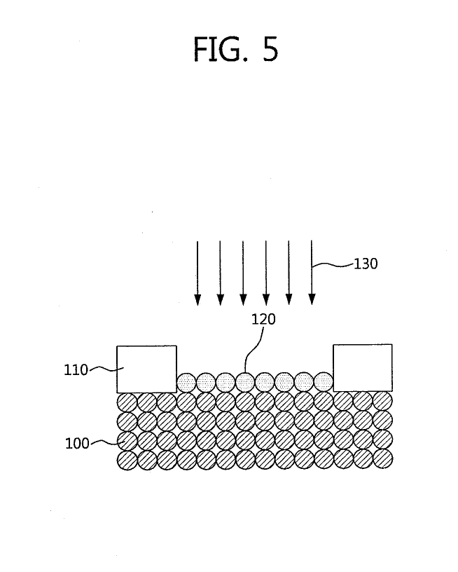

Referring to FIG. 5, the shutter 20 of the plasma generator 10 is opened and neutral beams are irradiated toward the layer 100 onto which the reactive radicals are adsorbed.

Here, electric power is applied to the grid assembly 13 installed at a lower part of the plasma chamber 11 to extract and accelerate the ionic material to extract ion beams, and the ion beams receive electrons and are converted into neutral beams by the reflective body 14. Here, a first grid 13a of the grid assembly 13 receives a positive (+) voltage, a second grid 13b receives a negative (−) voltage and a third grid 13c receives a positive (+) voltage.

Describing extraction of the ion beams and generation of the neutral beams, first, an ionic material existing in plasma in the plasma chamber 11 is extracted and accelerated through the first grid 13a, to which a positive (+) voltage is applied, to be extracted as ion beams, and the extracted ion beams are decelerated through the second grid 13b, to which a negative (−) voltage is applied. In addition, the decelerated ion beams are concenrated and accelerated through the third grid 13c, to which a positive (+) voltage is applied.

Further, the ion beams accelerated through the grid assembly 13 collide with the reflective body 14 to be reflected. The ion beams that have collided with the reflective body 14 acquire electrons to be neutralized by the reflective body 14. Therefore, the ion beams are converted into neutral beams.

Furthermore, acceleration energy of the neutral beams is adjusted such that sputtering is not generated from the surface of the layer 100. For example, voltages of the second grid 13b and the third grid 13c are adjusted such that the acceleration energy of the neutral beams is about 50 eV or less.

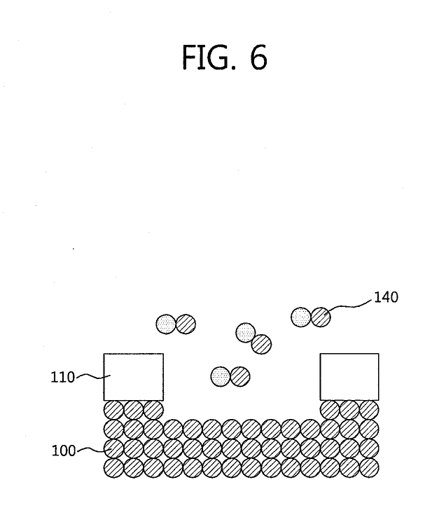

Referring to FIG. 6, when the neutral beams are irradiated to the layer 100, a material of the layer 100 adsorbed to the reactive radicals is detached and etched to be removed.

Next, the shutter 20 of the plasma generator 10 is closed to block irradiation of the neutral beams to the substrate 51, and a purge gas is supplied into the reaction chamber 80 through the purge gas supply pipe 70 to discharge the purge gas through the process gas discharge port 72 under control of the controller 40. Here, the purge gas is discharged with etching byproducts by etching of the layer 100, i.e., the material of the layer 100 adsorbed to the reactive radicals floating in the reaction chamber 80.

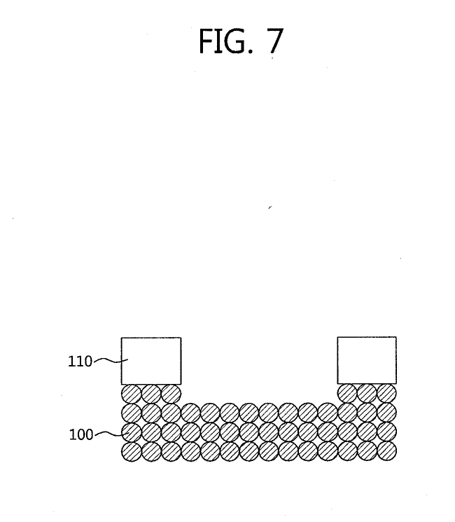

Referring to FIG. 7, when the purge gas and the etching byproducts are discharged, an atomic layer etching process of the layer to be etched is completed.

As described above, according to the present invention, unlike a conventional atomic layer etching method using an etching gas, the reactive radicals are adsorbed to the layer to be etched, and the surface material of the layer and the reactive radicals can be simultaneously removed using neutral beams to perform the atomic layer etching process.

Therefore, it is possible to perform the atomic layer etching process of various material layers, on which the conventional atomic layer etching process could not be performed.

While the example embodiments of the present invention and their advantages have been described in detail, it should be understood that various changes, substitutions and alterations may be made herein without departing from the scope of the invention.

What is claimed is:

1. An atomic layer etching apparatus comprising:
a reaction chamber including a stage on which a substrate to be etched is seated;
a plasma generator including a plasma chamber configured to supply reactive radicals and neutral beams into the reaction chamber and receive a source gas to generate plasma, an inductive coil configured to surround the exterior of the plasma chamber to generate an electric field, a grid assembly disposed at a lower part of the plasma chamber and including first, second and third grids for extracting ion beams, and a reflective body disposed under the grid assembly and configured to supply electrons to the ion beams to convert the ion beams into neutral beams;
a shutter installed between the plasma generator and the reactive chamber and configured to adjust supply of the neutral beams into the reaction chamber;
a purge gas supply part configured to supply a purge gas into the reaction chamber; and
a controller configured to control supply of the source gas, an etching gas and the purge gas, and opening/closing of the shutter.

2. The atomic layer etching apparatus according to claim 1, wherein the first, second and third grids of the grid assembly are spaced apart a predetermined distance from each other, and
the first grid receives a positive voltage, the second grid receives a negative voltage, and the third grid receives a positive voltage to extract and accelerate ion beams.

3. An etching method using an atomic layer etching apparatus, the method comprising:
loading a substrate, in which a layer to be etched is exposed, on a stage in a reaction chamber;
reactively supplying radicals generated from a plasma generator disposed at an upper part of the reaction chamber into the reaction chamber to adsorb the radicals to a surface of the exposed layer;
supplying a purge gas through a purge gas supply part installed at one side of the reaction chamber, and removing excessive radicals remaining after the adsorption;
irradiating neutral beams generated from the plasma generator to the layer to which the radicals are adsorbed, and removing a surface material of the layer with the radicals; and
supplying a purge gas and removing etching byproducts generated by irradiation of the neutral beams.

4. The etching method according to claim 3, wherein the plasma generator comprises:
a plasma chamber configured to receive a source gas to generate plasma, an inductive coil configured to surround the exterior of the plasma chamber to generate an electric field, a grid assembly disposed at a lower part of the plasma chamber and including first, second and third grids for extracting ion beams, and a reflective body disposed under the grid assembly and configured to supply electrons to the ion beams to convert the ion beams into neutral beams.

5. The etching method according to claim 4, wherein, in supplying the reactive radicals, electric power is not supplied to the grid assembly.

6. The etching method according to claim 4, wherein, in irradiating the neutral beams and removing the surface material of the layer to be etched and the radicals,
the first grid of the grid assembly receives a positive voltage, the second grid receives a negative voltage, and the third grid receives a positive voltage.

7. The etching method according to claim 4, wherein, in irradiating the neutral beams and removing the surface material of the layer to be etched and the radicals,
the voltages applied to the second and third grids are adjusted to control acceleration energy of the neutral beams such that sputtering is not generated from the surface of the layer to be etched.

8. The etching method according to claim 4, wherein in irradiating the neutral beams and removing the surface material of the layer to be etched and the radicals,
ion beams are extracted from an ionic material in plasma through the grid assembly, and converted into neutral beams by the reflective body disposed on a progression path of the extracted ion beams and then irradiated.

9. The etching method according to claim 3, wherein the purge gas is nitrogen gas.
